(19) United States
(12) Patent Application Publication
(10) Pub. No.: US 2006/0268692 A1
(43) Pub. Date: Nov. 30, 2006

(54) Transmission of electronic packets of information of varying priorities over network transports while accounting for transmission delays

(75) Inventors: Steven Wright, Roswell, GA (US); Andrew Vemon, Atlanta, GA (US)

Correspondence Address: WITHERS & KEYS FOR BELL SOUTH, P. O. BOX 71355, MARIETTA, GA, 30007-1355, US

(73) Assignee: BellSouth Intellectual Property Corp.

(21) Appl. No.: 11/141,460

(22) Filed: May 31, 2005

(51) Int. Cl. H04L 12/56; H04L 12/28; G01R 31/08; G08C 15/00; H04L 12/26; G06F 11/00; H04J 3/14; H04J 1/16; H04L 1/00; H04J 3/22; H04J 3/16

(52) U.S. Cl. 370/229; 370/465; 370/389

(57) ABSTRACT

Transmission of electronic packets of varying priorities is provided for while accounting for transmission delays to minimize the transmission delay for higher priority electronic packets such as real-time services packets including voice or video. One manner of accounting for transmission delays involves applying rules regarding whether certain conditions are met to determine whether to pre-empt transmission of a lower priority packet with transmission of a higher priority packet to minimize delay of transmission of the higher priority packets while minimizing the transmission delay burden imposed on the lower priority packets. Another manner of accounting for transmission delays involves limiting the number of real-time service packet streams that pass through a given link in a transport network based on a determination of how many real-time service packet streams may be concurrently carried by the link while maintaining the transmission delay below a pre-determined amount to thereby minimize the transmission delays through the transport network.

### TECHNICAL FIELD

The present invention is related to the transmission of electronic packets through a transport network. More particularly, the present invention is related to accounting for transmission delays for electronic packets of varying priorities to minimize the transmission delays that are imposed.

### BACKGROUND

Packet switched networks no longer carry only a standard electronic data packet. Packet switched networks are now used to carry real-time service electronic packets such as those for voice and video services. However, the packet switched networks must concurrently carry both standard electronic data packets, i.e., non-real-time service electronic packets, while also carrying real-time service electronic packets. Because both types of electronic packets are present at the same time, they compete for bandwidth and transmission time through links of the packet switched transport network.

The real-time service electronic packets are typically considered higher priority packets because a real-time service suffers from a relatively slow arrival of the electronic packets. To implement the higher priority of the real-time service electronic packets, one or more nodes or link endpoints of the transport network may either employ priority scheduling or pre-emptive scheduling for the transmission of the electronic packets. The packets are received from a source for a given link of the transport network and are placed in a queue awaiting transmission. The packets are classified according to priority in the queue and this priority is then used when scheduling the transmission order of the packets according to one of the scheduling schemes.

For priority scheduling, a higher priority electronic packet that is received for transmission is placed in the queue ahead of all other lower priority electronic packets. However, when a higher priority electronic packet is received into the queue while the transmission of a lower priority electronic packet has already begun, then the transmission of the higher priority electronic packet does not begin until transmission of the lower priority electronic packet has completed. While this reduces the transmission delay burden associated with the lower priority electronic packets, the drawback with this approach is that if the higher priority electronic packet is received just after transmission of the lower priority electronic packet has begun, then transmission of the higher priority electronic packet is delayed for a significant amount of time. This significant delay for the higher priority electronic packet may have an adverse effect on the quality of the real-time service for which the higher priority electronic packet corresponds.

For pre-emptive scheduling, a higher priority electronic packet that is received for transmission is placed in the queue ahead of all other lower priority electronic packets as with priority scheduling. However, for pre-emptive scheduling, every time a higher priority electronic packet is received into the queue while the transmission of a lower priority electronic packet has already begun, then the transmission of the lower priority electronic packet is pre-empted by transmission of the higher priority electronic packet. This is done by immediately stopping transmission of the lower priority electronic packet and immediately beginning transmission of the higher priority electronic packet. While this minimizes the transmission delays associated with higher priority electronic packets, the drawback is that the lower priority electronic packets may have lengthy transmission delays, especially where higher priority electronic packets are being received for transmission in rapid succession such that the lower priority electronic packets are essentially delayed until the succession of higher priority electronic packets ends.

When traveling through the network transport, the electronic packets are passed from link to link. Each link has a given bandwidth, typically measured in bits per second. Each link also has transmission delay resulting from the time an electronic packet waits in the queue of each link starting point plus the propagation time to pass from one starting point of the link to the end point. However, when networks are designed for routing the electronic packets, the concern is typically whether a particular link has adequate bandwidth to carry a given number of packets over a period of time. Thus, the number of streams of real-time services packets that are allowed to be concurrently carried by a particular link is based on the bandwidth of the link. While the link bandwidth may support a particular number of streams, the transmission delay for a particular link that result from concurrently carrying that number of streams is not negligible.

For subscribers of the real-time service who have relatively low bandwidth uplinks, such as asymmetric digital subscriber line service or cable modem service, the transmission delay associated with the uplink for the subscriber will be substantial due to the sharing of the uplink between one or more real-time services and standard data transmissions. If the cumulative delays through the network transport are also substantial, then the total transmission delay for the real-time service will likely be so large as to negatively affect the quality of the service.

### SUMMARY

According to exemplary embodiments, these issues and others are addressed by providing devices and methods that account for the transmission delays. Devices and methods may provide for pre-emption of lower priority electronic packets by higher priority electronic packets when conditions are met that call for such pre-emption, as opposed to always pre-empting the lower priority electronic packets. Additionally, devices and methods may provide for limiting the number of streams of real-time service electronic packets for a link of a transport network based on a pre-defined transmission delay threshold, as opposed to limiting the number of streams based on only bandwidth availabilities of the link.

According to an exemplary embodiment, a device is provided for transmitting electronic packets of information. The device includes a memory providing a queue for electronic packets to be transmitted and a transmission component that transmits electronic packets. The device further includes at least one processing device coupled to the memory and the transmission component that classifies the electronic packets to be transmitted according to priority and that pre-empts transmission of a lower priority electronic packet in order to transmit a higher priority packet when at least one specified condition is met by stopping transmission of the lower priority electronic packet and starting transmission of the higher priority packet.

According to another embodiment, a computer readable medium includes instructions for transmitting electronic packets wherein the instructions are for receiving electronic packets and classifying the packets according to priority. When transmission has begun for a lower priority packet and a higher priority packet to be transmitted is subsequently received, it is determined whether at least one specified condition is met for pre-empting transmission of the lower priority packet. When the at least one specified condition is met, then the on-going transmission of the lower priority packet is pre-empted in order to begin transmission of the higher priority packet.

According to another embodiment, a device for provides real-time service electronic packet transmission control that includes a communication component that receives electronic packets forming a request to establish a real-time service electronic packet stream. The device further includes at least one processing device coupled to the communication component. The processing device analyzes the request to thereby determine whether any links necessary to establish the real-time service electronic packet stream are currently at a maximum number of real-time service electronic packet streams where the maximum number for each link is based on a pre-determined maximum transmission delay allowed for each link. The processing device provides setup information in response to the request when none of the links necessary to establish the real-time service electronic packet stream are at the maximum number and provides a rejection in response to the request when at least one of the links necessary to establish the real-time service electronic packet stream is at the maximum number.

According to another embodiment, a computer readable medium has instructions for providing real-time service electronic packet transmission control for a network transport. The instructions provide for pre-determining a maximum number of real-time service electronic packet streams that may be concurrently carried by each of a plurality of link types so as to maintain a transmission delay of each link type below a transmission delay threshold specified for each link. The instructions further provide for pre-determining an expected number of concurrent real-time service electronic packet streams to be carried by links of the network transport and rendering a design for a network transport by, for at least one link of the network transport, choosing a link type that has the pre-determined maximum number of real-time service electronic packet streams that may be concurrently carried that is at least as many as the expected number of concurrent real-time service electronic packet streams to be carried by the at least one link.

According to another embodiment, a method provides for real-time service electronic packet transmission control for a network transport. The method involves determining a maximum number of real-time service electronic packet streams that may be concurrently carried by each of a plurality of link types so as to maintain a transmission delay of each link type below a transmission delay threshold specified for each link. The method further involves determining an expected number of concurrent real-time service electronic packet streams to be carried by links of the network transport. For at least one link of the network transport, choosing a link type that has the determined maximum number of real-time service electronic packet streams that may be concurrently carried that is at least as many as the expected number of concurrent real-time service electronic packet streams to be carried by the at least one link.

### DESCRIPTION OF THE DRAWINGS

FIG. 1 shows an illustrative network transport model for electronic voice packets to establish a real-time voice service.

FIG. 2 shows an illustrative set of modules of a network node such as the residential gateway of FIG. 1 that transport the electronic packets.

FIG. 3 shows an illustrative operational flow followed by the modules of the network node when transporting the electronic packets.

FIG. 4 shows a timeline of electronic packet transmission where the network node of FIG. 2 makes the determination that pre-emption of a lower priority packet by a higher priority packet should not occur.

FIG. 5 shows a timeline of electronic packet transmission where the network node of FIG. 2 makes the determination that pre-emption of a lower priority packet by a higher priority packet should occur.

FIG. 6 shows modules of an illustrative softswitch including an admission control scheme.

FIG. 7 shows an illustrative operational flow of the admission control scheme of the softswitch.

FIG. 8 shows the operational flow for designing a network based on delay constraints.

### DETAILED DESCRIPTION

According to exemplary embodiments, devices and methods provide for the transmission of electronic packets while accounting for transmission delay, such as by determining whether to pre-empt a lower priority packet with a higher priority packet and/or by limiting the number of real-time service streams carried by a particular link based on a transmission delay threshold. When accounting for the transmission delay in these manners, the transmission delay can be minimized so as to decrease any negative effect that transmission delay may have on a particular service.

Real-time services include services such as voice over Internet Protocol (VoIP) and video over Internet Protocol. These services are expected to happen in real time, and delays in transporting the voice or video electronic packets over the network transport can negatively impact the quality of the service to the subscriber. Therefore, these real-time services may be given a higher priority than standard data electronic packets and special treatment may be given to these higher priority electronic packets both when scheduling the higher priority electronic packets for transmission at a node and when selecting which links between nodes to employ to transport the electronic packets.

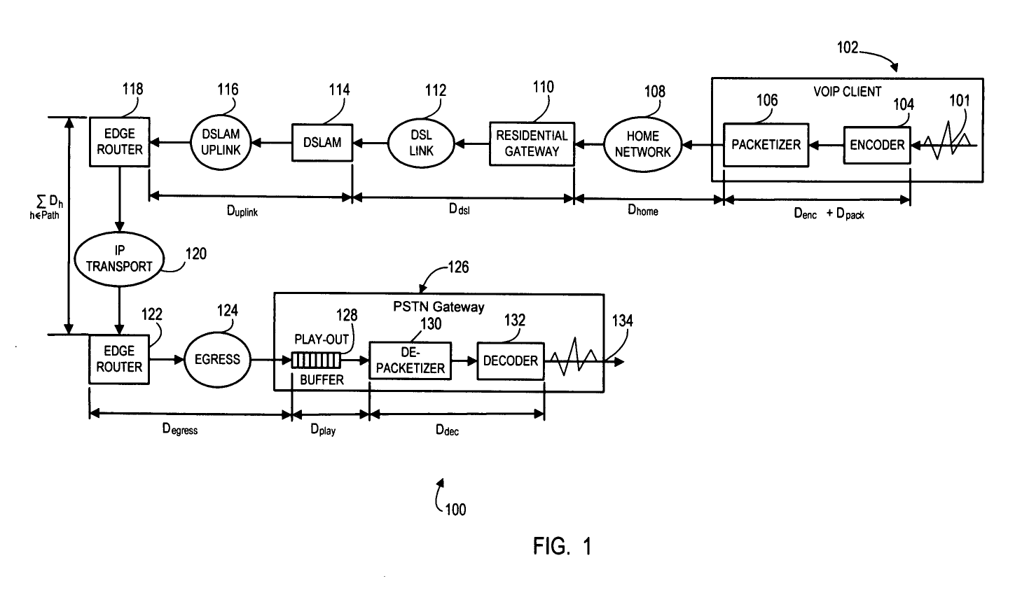

FIG. 1 shows one example of a transport model 100 for a voice service utilizing a digital subscriber line (DSL) uplink from the subscriber. In this example, the goal is to carry the voice to and from the subscriber, through the packet switched network transport, and to and from the public switched telephone network where the call is completed to the other party to the call. However, it will be appreciated that the devices and methods discussed herein also apply to other scenarios, such as for uplinks other than DSL, where the completion of the service is entirely through a packet switched network, such as a voice service completed over only an IP network transport, and/or where the service is for video or other real-time services in addition to or as an alternative to voice.

In FIG. 1, a non-encoded voice signal 101 is initially received by an encoder 140 via a VoIP client device 102. The encoder 104 provides an encoded voice signal to a packetizer 106. The packetizer 106 then outputs the electronic voice packets to a home network 108, which delivers the electronic voice packets to a residential gateway 110. It will be appreciated that other client devices may also be providing electronic packets through the home network 108 to the residential gateway 110 where the other packets compete with the real-time service packets for bandwidth and transmission time.

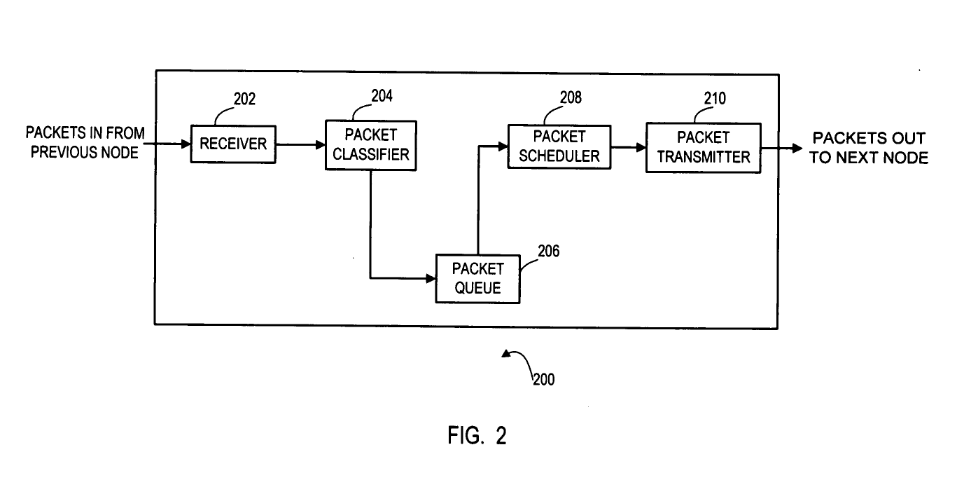

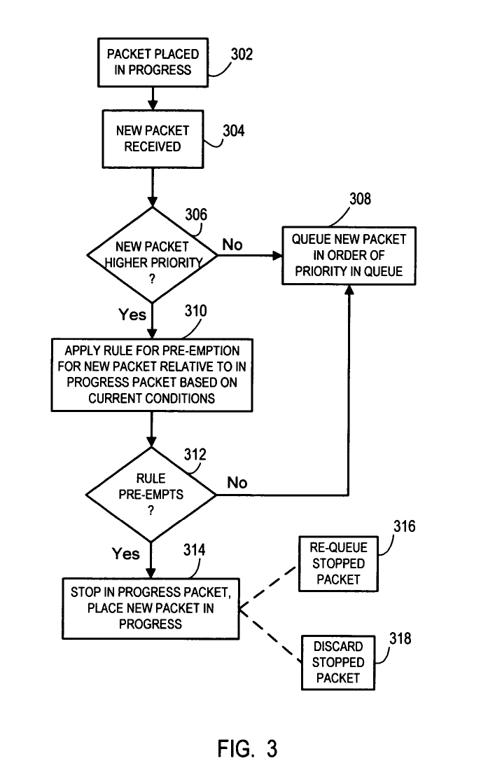

The residential gateway 110 of this example includes a DSL modem to upload the electronic packets, including, for example, voice packets from VoIP client 102 and standard data packets from other client devices. According to an exemplary embodiment, the residential gateway uploads these electronic packets according to a transmission schedule that has been determined based on the priority of the packets. The transmission schedule is discussed in more detail below in relation to FIGS. 2 and 3. It should be appreciated that the VoIP client 102 may also be included within the residential gateway 110 rather than being a separate device.

In this particular example of a network topology, the electronic packets are uploaded through a DSL link 112 between the residential gateway 110 and a digital subscriber line access multiplexer (DSLAM) 114. The DSLAM 114 serves as an endpoint for many DSL links leading to many subscribers. The DSLAM 114 then uploads these electronic packets via a DSLAM uplink 116 to an edge router 118. The DSLAM 114 may upload the electronic packets according to a transmission schedule that has also been determined based on the priority of the packets. It will be appreciated that real-time and non-real-time service electronic packets received at the DSLAM 114 from many DSL links must compete for uplink bandwidth and transmission time.

The edge router 118 routes the electronic packets on through the core IP transport 120 that includes a network of routers and switches that ultimately route the packets to another edge router. In this example, electronic voice packets are routed through the IP transport 120 to an edge router 122 which then sends the voice packets via an egress link 124 to a PSTN gateway 126. It will be appreciated that for an end to end packet switched transport, the edge router 122 could, for example, send the packets over another DSLAM link to another DSLAM which could then send the voice packets via another DSL link to another residential gateway and then to a destination VoIP client to complete the transmission.

Returning to the example shown, the PSTN gateway 126 includes a play-out buffer 128 which feeds received voice packets to a de-packetizer 130 where the voice information of the voice packets are pieced together to form an encoded voice signal that is supplied to the decoder 132. The decoder 123 then outputs a decoded voice signal 134 which proceeds through the PSTN until reaching the destination telephone (not shown). It will be appreciated that for the voice transmission from the PSTN back to the VoIP client, the PSTN gateway 126 encodes and packetizes the voice signal from the PSTN, and the resulting voice packets are sent to the edge router 122 where they are then sent back to edge router 118. From there, the voice packets travel to the voice client 102 along the same path, i.e., through the DSLAM link 116, DSLAM 114, residential gateway 110, and home network 108. Additionally, it will be appreciated that for a PSTN by-pass scenario where the call is between two VoIP clients, each VoIP client includes a depacketizer and decoder so that received VoIP packets may be converted into audible communications.

In each step of the model 100 shown in FIG. 1, there is an associated delay D that is the amount of time for the packet to be transmitted once received and the time for the transmitted packet to propagate over the link. A potentially substantial portion of the delay is the time the packet waits in the queue of the node before being transmitted. The total delay from the VoIP client 102 to the PSTN is the sum of each of the delays shown in FIG. 1. A typical acceptable delay of a signal through the PSTN is about 150-200 milliseconds. Therefore, it has been found that for acceptable voice service, the voice packet delay from the VoIP client 102 to a geographically proximate PSTN of about 50 milliseconds is preferable.

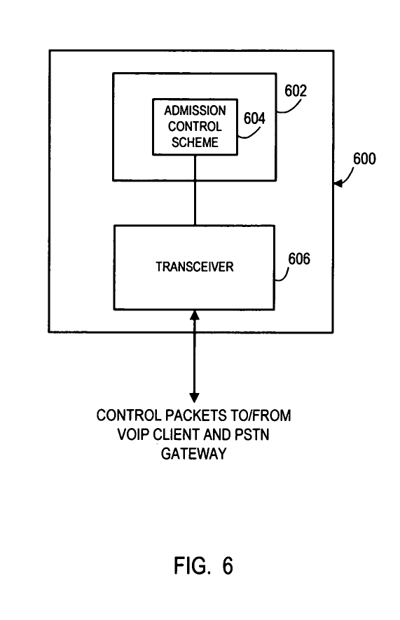

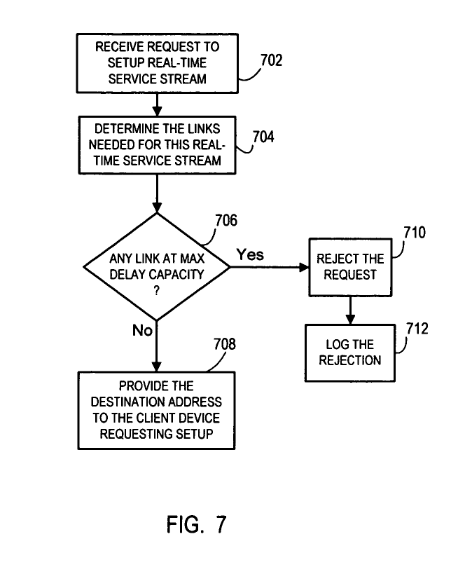

The delay from the DSLAM 114 to the PSTN gateway 126 for voice packets is within the control of the voice service provider. The devices and methods that may be employed by the service provider to minimize these delays are discussed below in relation to FIGS. 6 and 7. It is desirable to minimize the delays for the voice packets within the network transport core, i.e., upstream of the DSLAM, because the uplink from the residential gateway 110 to the DSLAM 114 is a substantial component of the overall delay that the service provider cannot control due to the limited bandwidth purchased by the subscriber. However, devices and methods may be employed to reduce the delay for the voice packets, or other real-time service electronic packets, at each of the links including the limited bandwidth uplink from the subscriber to the network transport.

FIG. 2 shows a node 200 which may include, e.g., the residential gateway 110 or DSLAM 114 of FIG. 1. The node 200 includes a receiver module 202 that receives incoming packets including non-real-time service packets, i.e., standard data packets, as well as real-time service packets such as voice and/or video packets. The packets may be received either in a wireless, wireline, or optical format depending upon the device 200 and the link to which it interfaces. Regardless of the format in which the packets are received, the receiver module 202 outputs the packets in electronic format. The receiver 202 passes the electronic packets on to a packet classifier module 204. The packet classifier module analyzes the packets for their type which sets forth their priority, either a real-time service electronic packet such as a voice packet that has a higher priority or a non-real time service electronic packet that has a lower priority. Packet classification typically occurs by examining the encoding of bits in the packet header information. There are standard mechanisms for encoding priority like this for layer 2 protocols, e.g. Ethernet uses the p bits in a VLAN header, and for layer 3 protocols where IP headers have bits reserved for the Type of Service (ToS) or Differentiated services code points.

Once the incoming packets are classified, they are placed into a packet queue module 206 which is a portion of memory that holds the electronic packets until they reach the front of the line for being transmitted. Higher priority packets are moved to the front of the line within the queue 206. Higher priority packets may also pre-empt lower priority packets currently being transmitted if one more specific conditions are met at the time the higher priority packet is placed into the queue 206. Whether the higher priority packet pre-empts the in-progress transmission of a lower priority packet is discussed in more detail below in relation to FIG. 3.

A packet scheduler module 208 retrieves packets from the queue 206 and presents them to the packet transmitter module 210 for transmission over a link. The packet scheduler module 208 employs the logic necessary to give effect to the higher priority of real-time service electronic packets and to implement pre-emption based on whether one or more conditions are met. The scheduler 208 recognizes the higher priority packets in the queue 206 and selects them for transmission ahead of lower priority packets in the queue 206. The scheduler 208 also determines whether to pre-empt in-progress transmission of lower priority packets with higher priority packets by detecting whether certain conditions are met, as opposed to always preempting the lower priority packets, so that the transmission of lower priority packets is not unnecessarily delayed.

When pre-emption does occur, the scheduler 208 may dictate that the lower priority electronic packet is not returned to the queue such that it is discarded, or may alternatively dictate that the lower priority electronic packet is returned to the queue such that it may be reattempted in the future without the transport layer, e.g. transport control protocol (TCP) of the communicating systems requesting a re-send of lost packets. Returning the lower priority electronic packet to the queue 206 may be especially useful for electronic packets being sent via the User Datagram Protocol (UDP) where the communicating systems do not necessarily request re-sends for lost packets.

The packet transmitter module 210 sends the packets over the link as they are received from the packet scheduler 208. The packet transmitter module 210 receives the packets from the scheduler 208 in electronic format. However, the packet transmitter module 210 may output the packets in one of various formats such as wireless, wireline, or optical depending upon the link interface.

While FIG. 2 has been described in relation to individual modules, it will be appreciated that one or more of these modules may be combined into a single module. Furthermore, these modules may be implemented separately or in combination in hardwired logic circuits, application specific processor circuitry, general purpose programmable processor circuitry in combination with dedicated purpose software or firmware, and the like. Additionally, it should be noted that the receiver module 202 and transmitter module 210 may be implemented as transceiving devices where the device 200 is required to send and receive in both directions of packet flow. The instructions necessary for performing the functions of each of the modules may be embodied within a computer readable medium which is a physical structure such as a magnetic or optical data storage disc or an electronic memory device from which the instructions may be accessed and performed.

FIG. 3 shows an illustrative set of logical operations that may be performed by the device of FIG. 2 when transmitting electronic packets in order to implement the selective pre-emption of the lower priority packets. The logical operations begin at transmission operation 302 where the scheduler 208 has placed an electronic packet in progress by presenting it to the transmitter 210. Thereafter at reception operation 304, a new electronic packet is received, classified, and placed into the queue 206. At query operation 306, the scheduler 208 then detects from the classification of the new electronic packet in the queue 206 whether the new electronic packet has a higher priority than the electronic packet for which transmission has begun.

The priority specified by how the new electronic packet has been classified ultimately determines whether the new electronic packet is eligible to pre-empt the in progress transmission. If it is determined at query operation 306 that the new electronic packet is not higher in priority than the packet in progress, then at queue operation 308 the scheduler 208 maintains the new electronic packet in the queue 206 with the new electronic packet being scheduled for transmission based on its order of priority among any other electronic packets also in the queue 206.

If the scheduler determines at query operation 306 that the new electronic packet does have a higher priority than the in progress packet, then the scheduler determines whether the higher priority packet should pre-empt the in progress transmission of the lower priority packet at rule operation 310. Here the scheduler applies a particular rule for pre-emption to determine whether pre-emption should occur. The rule sets forth at least one condition that must be met in order to pre-empt the in progress transmission of the lower priority packet.

The specifics of the rule to be applied for a given situation are a matter of design choice. However, various examples are provided solely for the purposes of illustration. As a first example, the in progress lower priority packet has a length of X bits left to be transmitted while the new higher priority packet has a length of Y bits in total. If X is greater than Y, then pre-empt. As a second example, the in progress lower priority packet has a length of X bits left to be transmitted and a pre-emption threshold is Z bits. If X is greater than Z, then pre-empt. The pre-emption threshold of Z bits may be a fixed value, or it may be based on a percentage of overall packet size such that it varies with the size of each lower priority packet being transmitted.

Additionally, there may be many levels of priority rather than only two. For example, a given link may carry voice packets, video packets, and standard data packets. The voice packets may be given highest priority, the video packets given next highest priority, and the standard data packets given lowest priority. In such a case, rules may vary depending upon the two types involved in the condition for pre-emption. For example, if a video packet is in progress when a new voice packet arrives for transmission, then the voice packet may pre-empt only if the remaining bits of the video packet are greater than a first pre-emption threshold of Z bits. However, if a standard data packet is in progress when a new voice packet arrives for transmission, then the voice packet may pre-empt only if the remaining bits of the standard data packet are greater than a second pre-emption threshold of N bits, where N is less than Z. Furthermore, if a standard data packet is in progress when a new video packet arrives for transmission, then the video packet may pre-empt only if the remaining bits of the standard data packet are greater than a third pre-emption threshold of P bits, where P is greater than N and less than Z.

Other conditions may also be considered besides the amount of the in progress packet yet to be sent. For example, downstream network congestion for one type of packet at a particular time might be greater than for another type of packet at that particular time. So, if congestion is greater for voice packets, it may be more advantageous to complete the transmission of an in progress data packet. Likewise, if congestion is greater for data packets, it may be more advantageous to begin transmission of a voice packet immediately even though the standard data packet has a relatively small amount yet to be transmitted. In those cases, the threshold for pre-emption may be altered based on the congestion factor, such as by temporarily setting the threshold to zero or to infinity or altering it by some set amount for that instant in time.

Additionally, these rules may be dynamic in that the thresholds may change through manual or automatic processes and/or rules may be added or removed. Therefore, the manner in which pre-emption occurs may be different at one time than at another for exactly the same circumstances because the rules that apply may have changed.

Once the rule has been applied based on the current condition(s) of interest, the scheduler 208 then determines whether the pre-emption should occur at query operation 312 based on the outcome of applying the rule. If the condition(s) are not met, then the new packet is maintained in the queue in order of its priority at queue operation 308. However, if the conditions are met, then the new packet pre-empts the in progress lower priority packet.

The rules may also take into account the arrival rate of the higher priority packets as a factor in determining whether pre-emption should occur. For example, the scheduler 208 may measure the number of higher priority packets being received over a unit of time and may then apply rules that correspond to the number of higher priority packets. For example, a rule may be applied such that no pre-emption occurs unless the number of higher priority packets received within a unit of time exceeds a given amount.

The number of higher priority packets received per unit time may fluctuate based on a number of real time service streams that are established through the network element employing pre-emption at any given time. So, for example, pre-emption may not be employed where only a single VoIP stream corresponding to a single call is occurring, whereas pre-emption is employed subject to other rules where two or more VoIP streams are occurring. Where the network element lacks the ability to determine the number of concurrent streams, the number is reflected by the number of higher priority packets received within a unit of time. As more concurrent streams occur, the number of higher priority packets per unit of time increases. Therefore, the threshold for pre-emption discussed above based on the number of higher priority packets per unit of time may be representative of the number of concurrent streams that trigger pre-emption.

The pre-emption occurs at pre-emption operation 314 where the scheduler 208 halts transmission of the lower priority packet and presents the new higher priority packet to the transmitter 210 to place the new packet in progress. At that point, one of two things may happen to the lower priority packet, again depending upon design choice. The lower priority packet may be re-queued at queue operation 316 so that once the higher priority packet(s) complete transmission, the lower priority packet will again be presented to the transmitter 210. As discussed above, this prevents the TCP layer between communication systems from requesting a re-send and prevents the packet from being entirely lost for UDP transactions where the client applications do not request re-sends. However, as an alternative, the lower priority packet may be removed from memory and not returned to the queue 206 at discard operation 318.

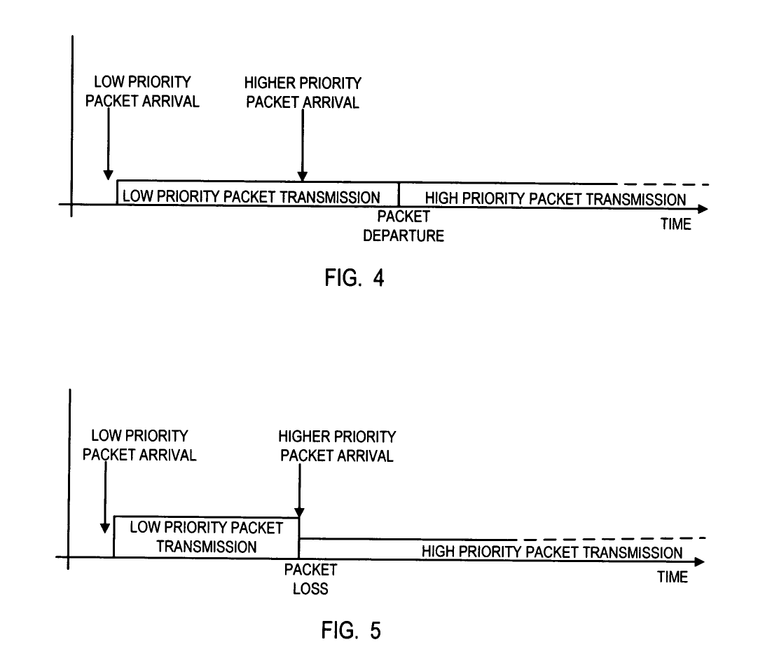

FIG. 4 shows a timeline of events where conditions specified by the rule for pre-emption are not met such that pre-emption does not occur according to an exemplary embodiment. As can be seen in FIG. 4, about the time the lower priority packet arrives, its transmission begins. Shortly thereafter and prior to transmission completing, the higher priority packet arrives. However, because the specified conditions are not met for the pre-emption rule, the higher priority packet does not pre-empt such that transmission of the lower priority packet continues while the higher priority packet waits in the queue. Once transmission of the lower priority packet completes such that the entire packet has departed, transmission of the higher priority packet immediately begins.

FIG. 5 shows a timeline of events where conditions specified by the rule for pre-emption are met such that pre-emption does occur according to an exemplary embodiment. Here, about the time the lower priority packet arrives, its transmission begins. Shortly thereafter and prior to transmission completing, the higher priority packet arrives. Because the specified conditions are met for the pre-emption rule, the higher priority packet does pre-empt such that transmission of the lower priority packet immediately ceases and the packet is lost unless re-queued, while transmission of the higher priority packet immediately begins.

In addition to pre-empting the transmission of non-real-time service packets with real-time service packets as discussed above in relation to FIGS. 1-5, it is also beneficial to minimize the overall delay that a real-time service packet experiences in traversing the network transport. The network transport between the real-time service client and the destination such as a media gateway includes a series of links, where each link is capable of a particular bandwidth and each link has a particular amount of utilization at a given point in time. Based on the available bandwidth of the links, the type of priority or pre-emption scheme employed by the end points of the links, and the size of the non-real-time service packets also being carried by the link, the expected transmission delay of real-time service packets for a link can be estimated. The total delay through the series of links is the cumulative amount.

The amount of acceptable delay for a real-time service is a design choice, but a total delay of 50 milliseconds or less for VoIP packets from a client to a geographically proximate PSTN is considered desirable. The transmission delay imposed by the uplink from the residential gateway is not controllable by the service provider but is a result of the bandwidth purchased by the subscriber. Furthermore, this transmission delay is significant in relation to the goal of 50 milliseconds of total transmission delay in the context of VoIP, even when pre-emption is applied as discussed above in relation to FIGS. 1-5.

Examples of transmission delays of DSL links for various hypothetical situations are shown below in Table 1, where the DSL link is employing pre-emptive scheduling as discussed above, where the non-real-time packet size that is competing for transmission time is set to be 1500 bytes, and where K is equal to the number of concurrent VoIP streams being carried.

TABLE 1

| | | K = 2 | | K = 3 | | K = 4 | | K = 9 | |
|---|---|---|---|---|---|---|---|---|---|
| | | Maximum | Average | Maximum | Average | Maximum | Average | Maximum | Average |
| DSL Link Type | | [ms] | [ms] | [ms] | [ms] | [ms] | [ms] | [ms] | [ms] |
| 256 | kbps | 8.28 | 3.43 | | | | | | |
| 384 | kbps | 5.52 | 1.52 | 11.04 | n/a | | | | |
| 512 | kbps | 4.14 | 0.86 | 8.28 | n/a | 12.42 | n/a | | |
| 1024 | kbps | 2.07 | 0.21 | 4.14 | n/a | 6.21 | n/a | 16.56 | n/a |

As can be seen, if two VoIP streams are being carried on a typical DSL uplink of 256 kbps, which may be a common occurrence in a household of multiple VoIP clients, then transmission delay can exceed eight milliseconds in certain cases. This leaves only about 41 milliseconds for the entire transport of the packet from the DSLAM to the PSTN gateway where the goal is 50 milliseconds or less. For heavy call volume situations such as a business setting where 9 VoIP calls are being handled concurrently, even with a bandwidth of 1024 kbps, the transmission delay for a voice packet may exceed 16 milliseconds. This leaves only about 33 milliseconds for the entire transport of the packet from the DSLAM to the PSTN gateway where the goal is 50 milliseconds or less.

It will be appreciated that where no pre-emption is applied, the transmission delay of real-time service packets for the DSL uplink is increased. Table 2 shows examples of transmission delays for various hypothetical situations where the DSL link is not employing pre-emptive scheduling and where the non-real-time packet size that is competing for transmission time is 40, 564, and 1500 bytes. From table 2, it can be seen that a single VoIP stream at a non-real-time packet size of 1500 bytes suffers from an average transmission delay that already exceeds the entire transmission delay goal of 50 milliseconds for the network transport. It can further be seen that for two concurrent VoIP streams with a non-real-time packet size of only 40 bytes, the average transmission delay is still nearly 50% greater than the maximum it may be when pre-emptive scheduling is employed. Thus, the benefits of pre-emption are without question.

TABLE 2

| DSL | | K = 1 | | | K = 2 | | | K = 3 | | | K = 4 | | | K = 9 | | |
|---|---|---|---|---|---|---|---|---|---|---|---|---|---|---|---|---|
| Link | | 40 | 564 | 1500 | 40 | 564 | 1500 | 40 | 564 | 1500 | 40 | 564 | 1500 | 40 | 564 | 1500 |
| Type | | [ms] | [ms] | [ms] | [ms] | [ms] | [ms] | [ms] | [ms] | [ms] | [ms] | [ms] | [ms] | [ms] | [ms] | [ms] |
| 256 | kbps | 3.28 | 21.38 | 53.75 | 11.56 | 29.66 | 62.03 | | | | | | | | | |
| 384 | kbps | 2.19 | 14.25 | 35.83 | 7.71 | 19.77 | 41.35 | 13.23 | 25.29 | 46.88 | | | | | | |
| 512 | kbps | 1.64 | 10.69 | 26.88 | 5.78 | 14.83 | 31.02 | 9.92 | 18.97 | 35.16 | 14.06 | 23.11 | 39.30 | | | |
| 1024 | kbps | 0.82 | 5.34 | 13.44 | 2.89 | 7.41 | 15.51 | 4.96 | 9.48 | 17.58 | 7.03 | 11.55 | 19.65 | 17.38 | 21.91 | 30.00 |

There may be many links involved in the particular path chosen for the packet. Therefore, when designing the network transport and when setting up new VoIP calls, consideration must be given to the transmission delays at each link in the path. It is desirable to make the transmission delay be negligible, e.g., one millisecond or less, for each link. Therefore, the total transmission delay is likely to be less than the goal of 50 milliseconds for a geographically proximate PSTN even when the DSL uplink transmission delay exceeds as much as 16 milliseconds.

To make the transmission delay be negligible, a determination must be made as to how many real-time service streams a given link type of a particular bandwidth can carry. Then, a path must be determined based on how many streams each potential link in the path is currently carrying relative to what the maximum number it may carry is for a given transmission delay limit. An example of the maximum number of VoIP streams various link types can carry is shown below in Table 3, where the number of streams each link type can carry when only bandwidth is considered is also shown for comparison.

TABLE 3

| | | Bandwidth-Limited | Delay-Limited Voice Capacity* | | | |
|---|---|---|---|---|---|---|
| | Link Speed | Voice Capacity | Preemptive | | Non-Preemptive | |
| Link Type | [kpbs] | (K*) | Utilization | Streams | Utilization | Streams |
| DS1 | 1,536 | 17 | — | — | — | — |
| 2xDS1 | 3,072 | 35 | 3.8% | 1 | — | — |
| 4xDS1 | 6,144 | 71 | 20% | 14 | — | — |
| 8xDS1 | 12,288 | 143 | 42% | 59 | 0.7% | 1 |
| DS3 | 43,000 | 502 | 79% | 396 | 60% | 300 |
| OC-3 | 148,608 | 1,736 | 94% | 1624 | 93% | 1614 |
| OC-12 | 594,824 | 6,948 | >95% | >6,600 | >95% | >6,600 |
| OC-48 | 2,377,728 | 27,777 | >95% | >26,400 | >95% | >26,400 |
| OC-192 | 9,510,912 | 111,108 | >95% | >105,500 | >95% | >105,500 |
| 10BaseT | 10,000 | 109 | 32% | 34 | — | — |
| 100BaseT | 100,000 | 1,091 | 90% | 981 | 89% | 970 |
| Gigabit Ethernet | 1,000,000 | 10,910 | >95% | >10,300 | >95% | >10,300 |

*Voice stream capacity for 99.999 percentile queuing delay to be less than 1 ms

As can been seen from Table 3, the number of VoIP streams that are concurrently supported where the delay for the link is maintained at less than one millisecond, whether for a pre-emptive link or non-preemptive link, is fewer than the number of VoIP streams that are concurrently supported where only bandwidth is of concern. Thus, for example, if links are chosen based on bandwidth capacity, a DS1 link can concurrently carry 17 VoIP streams. However, as indicated by the delay constraint of one millisecond, a DS1 link can carry no VoIP streams, regardless of whether pre-emption is employed or not. Thus, if a DS1 link is chosen to carry one or more VoIP streams, the transmission delay of the DS1 link becomes a non-negligible contributor to the overall transmission delay. Therefore, it is preferable to not utilize a DS1 link for VoIP packet streams.

Transmission delay information such as that of the example of Table 3 can be used when designing networks and determining whether new real-time service streams may be established for current conditions. For example, if it is known that a particular DSLAM must support a given number of customers who subscribe to a particular real-time service, then the DSLAM uplink is chosen to be a link type capable of supporting the number of concurrent VoIP streams that are likely to occur. If the number of concurrent VoIP streams of a given DSLAM uplink is likely to be more than 14, then the DSLAM uplink is provided as an 8×DS1 or faster link type.

Thus, when designing the series of links leading from the DSLAM or other entry node to the network transport all the way to the destination of the real-time service packets, delay constrained link limitations may be considered. Thus, so long as each of the links will be required to carry no more streams than has been predetermined for each link type, then the delay of the network transport is not detrimental to the service. The maximum number of streams to be carried by each link in the network transport can be derived by determining the number of subscribers for the real-time service whose packet streams will share a given link and by using historical call information that provides a basis for estimating future call volume. Once the estimated maximum has been found, then the appropriate link type may be chosen based on which link type can carry at least that many streams concurrently, as set forth in the example of Table 3.

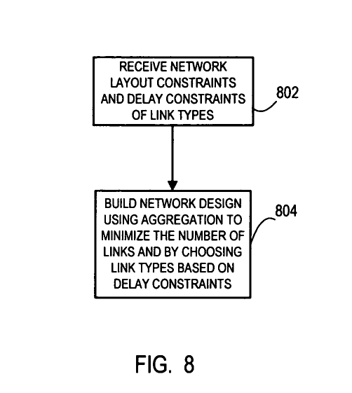

Thus, as shown in FIG. 8, the design of a network transport may be done may manually selecting each link for the network design and/or by providing a computer with constraints for the network layout and allowing the computer to select the links based on the constraints. Such constraints may include the expected number of real time service streams to be handled concurrently per end point and the number of end points. Delay constraints for each link type may also be input or otherwise determined, as in input operation 802. The computer may be executing instructions from a computer readable medium as previously discussed above in order to perform these design functions.

On the basis of the computer being provided with constraints, the computer may then choose the number of links and the link types to be employed throughout the network layout where the links are chosen based on the delay constraints for each link type relative to the number of concurrent real time service streams that are expected, as in design operation 804. The number and type of links may be chosen so that as the concurrent streams travel from the endpoints to deeper into the core of the network layout, they become aggregated at higher capacity links so as to minimize the number of links necessary within the network layout. However, the delay constraints of each necessary link, including those in the core of the network, may be factored into choosing some or all of the link types on the basis of the delay constraint information such as that provided in Table 3 that is based on some delay limit such as one millisecond that is selected to be allowable for the link type.

Once the link type for each of the links has been determined and put into practice in the network transport, the behavior of the network may then be controlled so as to maintain the real-time service network traffic within estimated conditions. As an example, at one point in time a DSLAM link is already carrying its maximum number of real-time packet streams, say 59 streams for an 8×DS1 DSLAM uplink. If a new real-time service stream is requested to be established by a client that relies on this 8×DS1 DSLAM, then the new real-time service packet stream may be rejected due to exceeding the delay constrained maximum of 59 for the DSLAM link. Details of rejecting the new stream are discussed in more detail below in relation to FIGS. 6 and 7.

For a real-time service, the real-time service client such as a VoIP client, must establish communication by obtaining call setup information, such as the destination address of a PSTN gateway, from a controller, such as a softswitch. A basic diagram of an illustrative softswitch 600 is shown in FIG. 6. The softswitch 600 is located within a packet switched network to which the real-time service client and the real-time service gateway has access. For example, the softswitch 600 may not reside within the IP transport 120 of FIG. 1 used to carry the actual real-time service packets, but instead may reside within a separate IP network that is also accessible by the edge routers 118 and 122. The softswitch 600 may send to and receive packets from the real-time service client 102 and the real-time service gateway 126 to provide the necessary call setup information to each to thereby establish an instance of the real-time service.

The softswitch 600 includes a processor module 602 that implements an admission control scheme 604 in order to receive requests to provide the necessary call setup information to allow a real-time service client to establish the packet stream to the destination address. The softswitch 600 receives such packetized requests and provides a packetized response via a transceiver module 606.

The admission control scheme 602 includes logic for determining whether the new real-time service packet stream can be supported in the network based on the conditions of the network at the time the request is received. Via the transceiver 606, the softswitch 600 is able to communicate with each of the devices forming the endpoints of each of the links between client devices and the gateways. The admission control scheme 602 may then determine whether any of the links needed to establish the new real-time service packet stream are already at their maximum capacity based on the delay constraints as set forth in Table 3.

If one or more of the necessary links are already at the maximum delay constrained capacity, then the admission control scheme 604 may then respond by declining to setup the new stream. For example, in the context of a VoIP stream, the softswitch may respond to a VoIP client by sending a busy tone or an audio message indicating that the network is unable to support the VoIP call at that particular time. The subscriber may then try again after some time has passed.

In rejecting the new stream, the softswitch 600 ensures that the delay constraints such as those of Table 3 are being enforced so that the network transport continues to function with the transmission delay as was expected when the network transport was designed. Accordingly, each link of the network transport is prevented from becoming a significant source of transmission delay. Records of such rejections may be maintained by the softswitch 600 along with an identification of the link or links that were at their maximum delay constrained capacity. The records may then be periodically reviewed to determine if particular links are frequently causing the rejection. If so, then those links may be upgraded to a faster bandwidth link type that can support more concurrent real-time service packet streams while maintaining the transmission delay at or below the length of time considered to be negligible.

FIG. 7 illustrates the logical operations of the admission control scheme 604. The operations begin at reception operation 702 where the admission control scheme 604 receives the request from the client device to setup the new real-time service packet stream, such as a VoIP call. The admission control scheme 604 at link operation 704 then determines the particular links of the network transport that are needed to deliver real-time service packets from the client device to the destination gateway or other destination device. At query operation 706, the admission control scheme 604 detects whether any of the identified links are already at the maximum delay constrained capacity, such as by referring to information in the example of Table 3.

Where it is found that none of the links are already at maximum delay constrained capacity, then the admission control scheme 604 sends setup information back to the client including the address of the destination device at send operation 708. However, if it is found that one or more of the links are already at the maximum delay constrained capacity, then the admission control scheme 604 sends a rejection message to the client device at rejection operation 710. The admission control scheme 604 may then also log the details of the rejection including the particular links that caused the rejection at log operation 712.

Again referring to Table 3, this information is provided as an example of delay constrained capacity of various link types. It will be appreciated that the maximum number of streams a link may carry is based on a transmission delay length that is chosen as the maximum amount that is considered to be negligible. Furthermore, it will be appreciated that the maximum number of streams is further based information including an assumed voice packet size. Several methods are available to calculate or estimate the expected delay for a voice stream in a packet network. See Sharafeddine, S., N. Kongtong, and Z. Dawry, “Capacity Allocation for Voice over IP Networks Using Maximum Waiting Time Models ”, Proceedings of ICT 2004. Also see Karam, M., and F. A. Tobagi, “Analysis of the Delay and Jitter of Voice Traffic over the Internet,” Proceedings of IEEE INFOCOM 2001. Karam and Tobagi describe one approach to this analysis. Sharafeddine, Kongtong and Dawry introduce a computationally more efficient approach.

While the invention has been particularly shown and described with reference to various embodiments thereof, it will be understood by those skilled in the art that various other changes in the form and details may be made therein without departing from the spirit and scope of the invention

What is claimed is:

1. A device for transmitting electronic packets of information, comprising:
memory providing a queue for electronic packets to be transmitted;
a transmission component that transmits electronic packets; and
at least one processing device coupled to the memory and the transmission component that classifies the electronic packets to be transmitted according to priority and that pre-empts transmission of a lower priority electronic packet in order to transmit a higher priority packet when at least one specified condition is met by stopping transmission of the lower priority electronic packet and starting transmission of the higher priority packet.

2. The device of claim 1, wherein the specified condition comprises an amount of the lower priority electronic packet that remains to be transmitted exceeds a pre-defined threshold.

3. The device of claim 2, wherein the pre-defined threshold is equal to the size of the higher priority electronic packet.

4. The device of claim 1, wherein the specified condition comprises a particular type of lower priority electronic packet is being transmitted.

5. The device of claim 4, wherein the lower priority packet is a non-real-time service acknowledgement electronic packet.

6. The device of claim 1, wherein the specified condition comprises network overhead associated with the lower priority differs from the overhead associated with the higher priority by at least a pre-defined amount.

7. The device of claim 1, wherein the lower priority packet is a non-real-time service data packet and the higher priority packet is a real-time service voice packet.

8. The device of claim 1, wherein the lower priority packet is a non-real-time service data packet and the higher priority packet is a real-time service video packet.

9. The device of claim 1, wherein the lower priority packet is a real-time service video packet and the higher priority packet is a real-time service voice packet.

10. A computer readable medium having instructions for transmitting electronic packets, comprising:
receiving electronic packets and classifying the packets according to priority;
when transmission has begun for a lower priority packet and a higher priority packet to be transmitted is subsequently received, determining whether at least one specified condition is met for pre-empting transmission of the lower priority packet; and
when the at least one specified condition is met, then pre-empting the on-going transmission of the lower priority packet in order to begin transmission of the higher priority packet.

11. A device for providing real-time service electronic packet transmission control, comprising:
a communication component that sends and receives electronic packets forming a request to establish a real-time service electronic packet stream; and
at least one processing device coupled to the communication component, the at least one processing device analyzing the request to thereby determine whether any links necessary to establish the real-time service electronic packet stream are currently at a maximum number of real-time service electronic packet streams where the maximum number for each link is based on a pre-determined maximum transmission delay allowed for each link, and wherein the at least one processing device provides setup information in a response to the request when none of the links necessary to establish the real-time service electronic packet stream are at the maximum number and provides a rejection in response to the request when at least one of the links necessary to establish the real-time service electronic packet stream is at the maximum number.

12. The device of claim 11, wherein the maximum number of real-time service electronic packet streams for at least one link is based on the utilization of pre-emption for real-time service electronic packets by that particular link.

13. The device of claim 11, wherein a real-time service packet is a voice packet and wherein the pre-defined maximum number of streams for each link is based on a one millisecond transmission delay.

14. A computer readable medium having instructions for providing real-time service electronic packet transmission control within a network transport, comprising:
pre-determining a maximum number of real-time service electronic packet streams that may be concurrently carried by each of a plurality of link types so as to maintain a transmission delay of each link type below a transmission delay threshold specified for each link;
pre-determining an expected number of concurrent real-time service electronic packet streams to be carried by links of the network transport; and
rendering a design for the network transport by, for at least one link of the network transport, choosing a link type that has the predetermined maximum number of real-time service electronic packet streams that may be concurrently carried that is at least as many as the expected number of concurrent real-time service electronic packet streams to be carried by the at least one link.

15. The computer readable medium of claim 14, wherein pre-determining the maximum number of real-time service electronic packet streams that may be concurrently carried by each link type comprises determining the maximum number that results from applying pre-emption for real-time service electronic packets.

16. The computer readable medium of claim 14, wherein the real-time service electronic packet streams are voice and the transmission delay threshold for each link is I millisecond.

17. The computer readable medium of claim 14, further comprising instructions for:
receiving non-real-time service electronic packets and real-time service electronic packets at a starting point of the at least one link;
when transmission has begun for a non-real-time service electronic packet at the starting point and a real-time service electronic packet to be transmitted is subsequently received at the starting point, determining whether at least one specified condition is met for pre-empting transmission of the non-real-time service electronic packet; and
when the at least one specified condition is met, then pre-empting the on-going transmission of the non-real-time service packet in order to begin transmission of the real-time-service packet from the starting point of the at least one link.

18. The computer readable medium of claim 17, wherein the real-time service electronic packet is a voice packet and the non-real-time service electronic packet is a standard data packet.

19. The computer readable medium of claim 17, wherein the real-time service electronic packet is a video packet and the non-real-time service electronic packet is a standard data packet.

20. A method for providing real-time service electronic packet transmission control for a network transport, comprising:
determining a maximum number of real-time service electronic packet streams that may be concurrently carried by each of a plurality of link types so as to maintain a transmission delay of each link type below a transmission delay threshold specified for each link;
determining an expected number of concurrent real-time service electronic packet streams to be carried by links of the network transport; and
for at least one link of the network transport, choosing a link type that has the determined maximum number of real-time service electronic packet streams that may be concurrently carried that is at least as many as the expected number of concurrent real-time service electronic packet streams to be carried by the at least one link.
